(19) United States
(12) Patent Application Publication
(10) Pub. No.: US 2026/0259933 A1
(43) Pub. Date: Sep. 3, 2026

(54) METHOD AND SYSTEM FOR PROCESSING ANALYSIS TASKS REGARDING COMPUTATIONAL ANALYSES OF INDUSTRIAL SYSTEMS DATA

(71) Applicant: NUOVO PIGNONE TECNOLOGIE -S.R.L., Florence (IT)

(72) Inventors: Giacomo VENERI, Florence (IT); Leonardo FRANCALANCI, Florence (IT); Matteo IANNITELLI, Florence (IT); Michele LAURIOLA, Florence (IT); Giuseppe SALERNO, Florence (IT)

(21) Appl. No.: 18/871,335

(22) PCT Filed: Jun. 6, 2023
(86) PCT No.: PCT/EP2023/025268

§ 371 Date: Dec. 3, 2024

(30) Foreign Application Priority Data
Jun. 8, 2022 (IT) 102022000012074

(51) Int. Cl. G06F 16/903

(52) U.S. Cl. CPC G06F 16/903

(57) ABSTRACT

Data from an industrial system are preliminarily stored in a data database making an assessment on the industrial system; an execution engine: a) collects execution parameters from a computational analysis computer program corresponding to an analysis, b) extracts from the data database data coming from the industrial system to be processed by the computational analysis computer program based on the collected execution parameters, c) creates an execution environment containing the extracted data, and d) executes the computational analysis computer program using the created execution environment.

### TECHNICAL FIELD

The subject matter disclosed herein relates to methods and systems for making assessments on a plurality of industrial systems, in particular to execution of analysis tasks.

### BACKGROUND ART

It is common making assessments on an (installed and operating) industrial system, i.e. the system as whole or a subsystem thereof or a component thereof; the “item” to be specifically assessed may be for example an Oil & Gas plant or a plant machine, in particular a turbomachine, or a machine component. An assessment may be a determination of some form of status of the “item” (for example the efficiency of a machine considering operation in the last hour or day or week) or of some form of prediction regarding the item (for example how many hours a machine may operate before next failure or anomalous condition).

It is also common that a same assessment may be repeated e.g. periodically (for example once per day or week or month).

A solution for making assessments on an “installed product” is described in patent document U.S. Pat. No. 10,628,145; this document uses the expression “execute analytic model”. Although this document mentions in general the possibility of assessing a plurality of industrial systems, it focuses on a first side on the structure of the “execution platform” (see FIGS. 2 and 3) on a second side on the analytic model and how to make it flexible (see FIGS. 5-9). As it is apparent from its description, it is possible that according to its invention more than one “model” (that, according to the terminology of the present specification, roughly corresponds to “computational analysis”) is applicable to a single “installed product” (that, according to the terminology of the present specification, roughly corresponds to “industrial system”), and a single “model” may be split into a plurality of “tasks” (that has no terminological correspondence in the present specification, and does not correspond to the “tasks” of the present specification). Only one paragraph in this document states that its system may receive “data from at least one of the installed product”. In the light of its background section, no details are provided in this document regarding how to deal with a plurality of models at the same time and how to deal with a plurality of installed products at the same time.

As all the independent claims of this patent document express as a necessary feature for the solution, its system and method require an “API wrapper” (which has not to be confused with a simple API) associated with the analytic model and with the execution platform, and the API wrapper, as a package of APIs, includes (an interface to) input information, (an interface to) output information and (an interface to) a “technique”; according to this document, the technique may be a solution methodology, a method that generates specific values of coefficients in a kernel, a relationship between inputs and outputs.

More in detail, the solution of this patent document provides a storage in communication with the analytic model and with the execution platform and storing program instructions to perform the functions as follows: transmitting information between the analytic API wrapper and the execution platform API wrapper; and deploying the analytic model to the execution platform based on the transmitted information.

Furthermore, the solution of this patent document provides that a “container module” may wrap each analytic model in a “complete filesystem” that may contain everything needed to run the model (e.g., code, runtime, system tools, system libraries, and anything that may be installed on a server). In fact, a model may be built on a local computer and then the model is transmitted to another computer to be executed; however, running the model on a computer different from where it was built may involve re-writing the model program and de-bugging the program, which may be very time consuming and error-prone; this re-writing/de-bugging process may be repeated each time the model is run on another system; it would therefore be desirable to provide systems and methods to facilitate model construction for a physical system in a more efficient and accurate manner. The “complete filesystem” mentioned above contributes significantly to satisfy the desire set out in U.S. Pat. No. 10,628,145.

As far as can be understood from this patent document, there is one execution platform with one execution module, and the various analytic models are configured to act directly on the input data through the input information of the API wrapper and on the output data through the output information of the API wrapper. The “API wrappers” of the analytic model and of the execution platform are essential for satisfying the desire set out in U.S. Pat. No. 10,628,145. Furthermore, it is provided that each of the analytic models is adapted to operate differently, presumably, according to specific requirements of the user or users, depending on the technique of the API wrapper; in this way, an analytic model may be customized on the flight.

A company may be interested in making several assessments on a plurality of industrial systems at the same time. It is to be understood that herein “at the same time” means during and within a same time period and does not mean necessarily contemporaneously (even if contemporaneity is not to be excluded); in fact, as disclosed herein, the level of contemporaneity depends on when analysis tasks are prepared and on how analysis tasks are processed.

Therefore, it would be desirable to have methods and systems for making such assessments; in particular, it would be desirable to they are flexible and/or efficient and/or effective.

### SUMMARY

According to a first aspect, the subject matter disclosed herein relates to an assessment method. Data from an industrial system are preliminarily stored in a data database for making an assessment on the industrial system; an execution engine: a) collects execution parameters from a computational analysis computer program corresponding to an analysis, b) extracts from the data database data coming from the industrial system to be processed by the computational analysis computer program based on the collected execution parameters, c) creates an execution environment containing the extracted data, and d) executes the computational analysis computer program using the created execution environment.

According to a second aspect, the subject matter disclosed herein relates to an assessment system. The system comprises an execution engine that has access to at least one computational analysis computer program and a data database storing data collected from industrial systems. In order to process an analysis task, the execution engine is configured to create an execution environment containing appropriate data extracted from the data database and to execute the computational analysis computer program using the created execution environment. Preferably, the execution engine is configured to identify the analysis task in an execution queue. Preferably, the execution engine is also configured to store results of execution in a results database.

According such system and method, the “execution environment” contains primarily data extracted from the data database (i.e. all the data to be processed already suitably selected and arranged), and optionally execution parameters. A reference to the computational analysis computer program to be executed (for example, its name and/or a link to its code) or a portion of the program or the whole program may also be contained in the “execution environment”. Therefore, they follow a completely different approach from the one of U.S. Pat. No. 10,628,145.

### BRIEF DESCRIPTION OF THE DRAWINGS

A more complete appreciation of the disclosed embodiments of the invention and many of the attendant advantages thereof will be readily obtained as the same becomes better understood by reference to the following detailed description when considered in connection with the accompanying drawings, wherein:

FIG. 1 shows a general schematic diagram of an embodiment of a system for making assessments on a plurality of industrial systems providing both preparation of analysis tasks and execution of the prepared analysis tasks,

FIG. 2 shows a flow chart of an embodiment of a method for making assessments on a plurality of industrial systems including preparation of analysis tasks, and

FIG. 3 shows a flow chart of an embodiment of a method for making assessments on a plurality of industrial systems including execution of analysis tasks.

### DETAILED DESCRIPTION OF EMBODIMENTS

According to the subject matter disclosed herein a plurality of industrial systems, for example a plurality of machines of Oil & Gas plants at different locations, are accessed at the same time. Data from the industrial systems are collected from the industrial systems and stored in a data database. Information regarding the industrial systems are stored in a systems database. Using these two databases an orchestrator, for example an application running on a server, prepares analysis tasks required for the assessments of the industrial systems in a flexible way and stores them in one or more execution queues; the preparation of analysis tasks is continuous, is repeated by scanning the systems database and is independent from the collection of data from the industrial systems. Furthermore, independently from the collection of data and from the preparation of analysis tasks, one or more execution engines continuously execute analysis tasks; each analysis task is executed by creating preliminarily a corresponding execution environment so that execution is effective and efficient. Typically, the analysis tasks are identified in one or more execution queues so that execution is even more effective and efficient. As already clarified, herein “at the same time” means during and within a same time period and does not mean necessarily contemporaneously (even if contemporaneity is not to be excluded); in fact, as disclosed herein, the level of contemporaneity depends on when analysis tasks are prepared and on how analysis tasks are processed. It is to be noted that different assessments are designed to operate on different data. Furthermore, it is to be noted the same assessment may be applied to different data (for example from different items) and this leads to distinct analysis tasks.

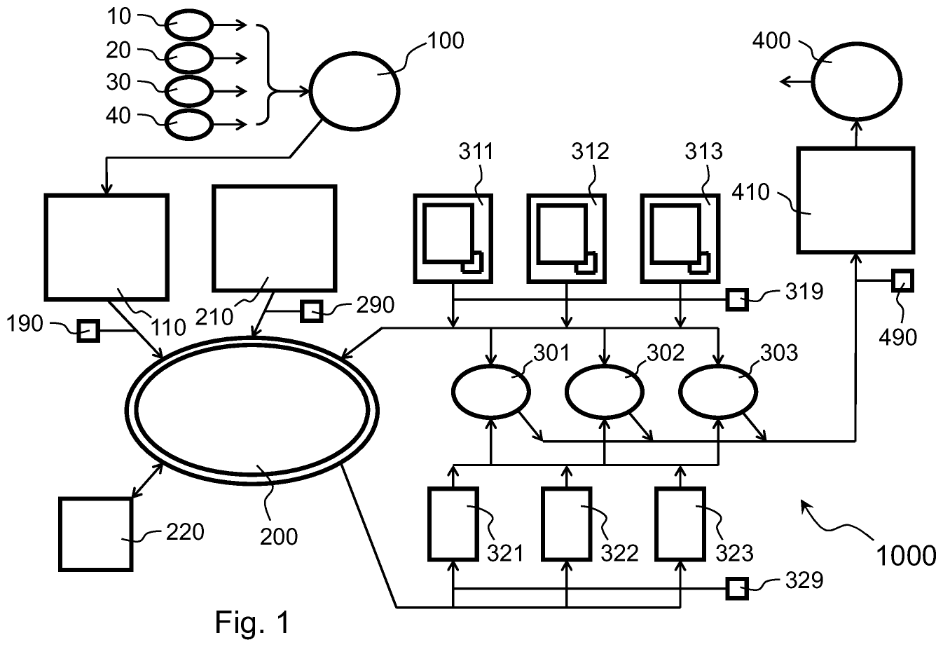

FIG. 1 shows an embodiment of a system 1000 for making assessments on a plurality of industrial systems, referred in the following as “innovative assessment system” or simply “assessment system”

FIG. 1 shows also a plurality of industrial systems external to assessment system 1000. In particular, the figure shows four industrial systems 10, 20, 30 and 40; however, any number of industrial systems may be considered from a minimum of one.

Data from industrial systems 10, 20, 30 and 40 to be assessed are repeatedly, for example periodically, collected and stored in data database 110; data are orderly stored in data database 110 so that they can be selectively retrieved afterwards. Data from a system may be of the same type (for example, temperature data at a certain position of a machine or pressure data at a certain position of a machine) or, more typically, of different types (for example, temperature data at several positions a of machine, or temperature data and pressure data at a certain position of a machine, or temperature data and pressure data at several positions a of machine, or data from several components of a machine and/or from several machines). Data for assessments may be measured data and/or computed data; measured data derive from sensors in an industrial system to be assessed; computed data derive from a processing circuitry in an industrial system to be assessed and processing may be performed by an analog and/or digital circuitry including a computer on locally measured data.

Data from industrial systems 10, 20, 30 and 40 may be received by a data input application 100, typically a software application running on a piece of hardware; part of this piece of hardware may be dedicated to data reception and possibly data transmission (for example for interrogation purposes). Application 100 may be configured not only to receive data but also to interrogate repeatedly, for example periodically, industrial systems 10, 20, 30 and 40 (in particular communication devices of the systems) and/or to receive data repeatedly, for example periodically, when an industrial system transmits them to assessment system 1000. An industrial system may gather (similar or different) measured and/or computed data for some time; such group of gathered data may be sent to assessment system 1000 as a data package when assessment system interrogates the industrial system and/or when the industrial systems decides to.

Application 100 may be configured also to (orderly) store received data in data database 110. Received data may also be processed by application 100 before being stored. Considering that in general data are received from several different (even very different) industrial systems, an effective form of processing may consist, for example, in labelling data in a uniform manner before storage; temperature data at the air inlet of a gas turbine may be labelled “T-A-I-GT” irrespective of e.g. the type and the size of the gas turbine.

Information regarding the industrial systems to be assessed are stored in a systems database 210. Such information regards in particular applicability relationship of computational analysis computer programs to data from industrial systems. In the embodiment of FIG. 1, by way of example, three analysis computer programs 311, 312 and 313 are provided and four industrial systems 10, 20, 30 and 40; for example, program 311 may be applicable to data from systems 10 and 20, program 312 may be applicable to data from system 30 and 40 and program 313 may be applicable to only one system (e.g. system 10) or to all systems.

It is to be noted that, according to some embodiments, some data in data database 110 may derive indirectly from industrial systems 10, 20, 30 and 40. Such data may derive e.g. from processing carried out by system 1000 or under control of the system 1000 on data received from an industrial system; for example, such data may correspond to “measurements” of a “virtual sensor” computed by an execution engine of e.g. system 1000. As will be more clear from the following, such data may be transferred from database 410 to database 110 under the control of application 100 and/or application 400.

A computational analysis computer program is a computer program, i.e. a piece of software, that is configured to be run by a computer, i.e. a piece of hardware, and that is designed to perform a computational analysis on specific data from one or more industrial systems in order to make an assessment on the one or more industrial systems, i.e. to determine some form of status or some form of prediction.

Systems database 210 may be embodied for example like a table having a row for each industrial systems considered by the “assessment system” and having a column for each “computational analysis” (that may be called also “analytic”) provided in the “assessment system”, corresponding to computational analysis computer programs; in any row, cells are marked for the “computational analyses” applicable to the industrial system corresponding to the row. Other columns may advantageously be provided in the table in order to categorize the industrial systems, for example one or more of the following category columns: “client” (i.e. the client name of the plant including the industrial system), “site” (i.e. the plant including the industrial system), “model” (i.e. the model of the industrial system), “name” (i.e. the name identifying the industrial system). Other columns may advantageously be provided in the table corresponding to parameter(s) and/or constant(s) useful when coupling an analysis program to one or more systems and/or when executing analysis tasks. Still one or more other component columns may advantageously be provided named e.g. “component-name” and/or “component-model” corresponding to one or more components providing data and that may be subject to assessment. Finally, one or more other time columns may advantageously be provided named e.g. “installation date” and/or “maintenance date” so that an assessment may take into account also such information.

It is to be noted that such systems database allows a lot of flexibility to the “innovative assessment system”. If, at a certain point in time, a further industrial system is to be considered by the “assessment system”, it is sufficient to add a row to the table and to introduce appropriate data/information. If, at a certain point in time, a further “computational analysis” is to be performed, it is sufficient to add a column to the table and to introduce appropriate data/information. If, at a certain point in time, a new “computational analysis” is to be applied to data from an industrial system, it is sufficient to introduce appropriate data/information into a cell of the table. If a specific “computational analysis” should be applied to the data from a set of “items”, the category columns may help in selecting the “items”.

Using systems database 210 and data database 110 an orchestrator 200, for example an application running on a server, prepares analysis tasks required for the assessments of industrial systems 10, 20, 30 and 40. It is to be noted that in the present description reference 200 is used to identify both an application and a server running this application; however, in general, a server running the orchestrator application may run one or more other applications. Orchestrator application 200 orchestrates the various databases in order to create analysis tasks. Orchestrator application 200 runs independently from the data input application 100; typically, they run on two distinct servers or two distinct virtual machines in the same server. As will be explained later, orchestrator application 200 is associated with an orchestrator database 220 that stores data and information for supporting the operation of the application.

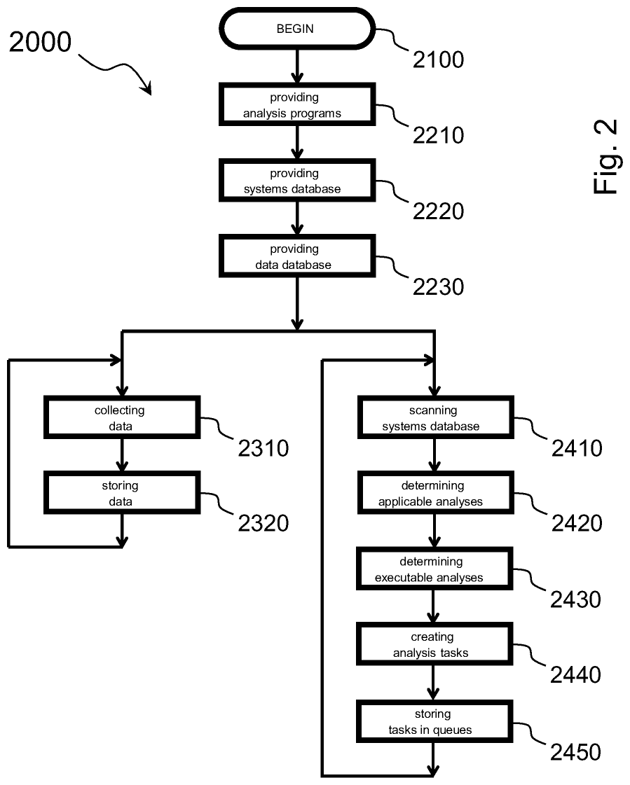

An “innovative assessment method” taking care of the preparation of analysis tasks will now be described with the aid of the flow chart 2000 in FIG. 2.

In FIG. 2, there is an initial block 2100 corresponding to the ideal start of this method.

This method comprises the preliminary steps of:
providing a plurality of computational analysis computer programs (block 2210 in FIG. 2),
providing a systems database (block 2220 in FIG. 2).

It is to be noted that additional computational analysis computer programs may be added at later times for example when designed, developed and tested.

It is to be noted that any “computational analysis computer program” may have been developed by a manager of the assessment system (for example system 1000) or by a manger of an industrial system (for example system 10, 20, 30 or 40).

It is also to be noted that the systems database may be updated at later times for example due to addition of industrial systems to be assessed and/or addition of “computational analysis” to be applied to collected data.

As a preliminary step, a data database may be provided (block 2230 in FIG. 2); initially, the data database is typically empty as no data has already been collected from the industrial systems.

Essentially two applications runs independently according to this method: the data input application (labelled 100 in FIG. 1) and the orchestrator application (labelled 200 in FIG. 1).

The data input application collects data from the industrial systems repeatedly (block 2310 in FIG. 2) and then stores them in the data database (block 2320 in FIG. 2).

The orchestrator application repeatedly:
a) (block 2410 in FIG. 2) scans the systems database,
b) (block 2420 in FIG. 2) for each industrial system in the systems database determines any computational analysis computer programs to be applied to data—one or more “computational analysis” may be applied to data collected from an industrial system—only under exceptional circumstances an industrial system registered in the systems database is not subject to any assessment,
c) (block 2430 in FIG. 2) for the determined computational analysis computer programs checks whether there are corresponding data in the data database—depending on the “computational analysis” to be applied there should be a certain quantity and/or quality of data in order to allow computation,
d) (block 2440 in FIG. 2) for each determined and positively-checked computational analysis computer program creates an analysis task to be executed, and
e) (block 2450 in FIG. 2) progressively stores the created analysis tasks in at least one execution queue.

Any item in an execution queue, i.e. any analysis task, may contain at least the following information:
name or identifier of the computational analysis computer programs to be executed
name or identifier of the industrial system (or systems) to be assessed, i.e. to be subjected to analysis by the program-more in general, identification of the industrial system or systems to be analyzed through the task, for example a set of systems belonging to a same category or categories
timeframe, i.e. time range of data of the industrial system to be analyzed

As it will explained later, any item of an execution queue will be processed separately by an execution engine so to perform the required “computational analysis”.

Typically, the orchestrator application determines any computational analysis computer programs to be applied to data based on information stored in the systems database—see step b.

The orchestrator application may check whether there are corresponding data in the data database based on information stored in in configuration files associated to the computational analysis computer programs—see step c.

As shown for example in FIG. 1, each computational analysis computer programs 311, 312, 313 is associated to a configuration files (see smaller box behind the bigger box) that contains information regarding the program; such information may be the type and amount of data from industrial systems that the program is designed to process, and possibly additionally whether it is 32-bit code program or a 64-bit code program and/or the operating system to be used for execution and/or whether it is a high-priority or a low-priority “computational analysis” and/or whether it is a “computational analysis” under-test or already-tested.

Typically, the orchestrator application checks whether there are corresponding data, in particular adequate and/or sufficient data, in the data database for a desired “computational analysis”—see step c. Such check may be based on information stored in the data database; in other words, the orchestrator application may query the data database and check the presence of data. Preferably, such check may be based also on information stored in an orchestrator database; for example, if “computational analysis” is performed periodically, the orchestrator application may check in the orchestrator database when it was performed last time and consequently whether there are adequate and/or sufficient data in the data database from last execution.

It is to be noted that if data necessary for a desired current “computational analysis”, i.e. “analysis A” come from a processing of a previous “computational analysis”, i.e. “analysis B”, for example a “virtual sensor”, there is a sort of dependency between “analysis A” and “analysis B”.

Advantageously, the orchestrator application may check whether a “computational analysis” is already in execution; such check is useful in order to avoid that e.g. for the same industrial system or for the same industrial systems an analysis on later data is performed before having finished the same analysis on previous data. This check may be performed for example by storing a “exec-state” information e.g. in the orchestrator database that indicates the “current execution state” of a program for one/any or more or all available computational analysis computer programs and/or for one or more or all execution tasks in execution.

Such “exec-state” information or an equivalent information may advantageously be used by the orchestrator application in order to check if a “computational analysis” is “locked” and/or “slow”. Such “exec” information may be supplemented by a “start-of-exec” information that allows to know when execution of a certain “computational analysis” started execution. The orchestrator may check, for one or more or all tasks in execution, whether execution time is longer than a predetermined maximum time length; if yes, the execution may be stopped and the “computational analysis” may be considered as non-performed; according. The predetermined maximum time length may vary from computational analysis computer program to computational analysis computer program.

Advantageously, the orchestrator application progressively stores the created analysis tasks in a plurality of execution queues (see for example queues 321, 322, 323 in FIG. 1). In particular, FIG. 1 shows three execution queues 321, 322 and 323; however, any number of queues may be considered from a minimum of one. A plurality of execution queues is useful for distribution the computational analysis work between several execution engines; distribution may be even or uneven.

An execution queue may be associated to one or more specific execution engines or one or my types of execution engines. For example, there may be a queue dedicated to an execution engine able to execute programs with a certain word-length or able to execute programs designed for a certain operating system or able to execute computation particularly intensive tasks or dedicated to high-priority “computational analyses”. An execution queue may be associated to a debug execution engine; this may be useful to testing and debugging a new “computational analyses”. It is to be noted that, in this way, debug may be performed on data being “real data” and coming for one or more industrial systems—so-called “fleet level debug”. It is also to be noted that a “computational analysis” to be debugged may have been previously developed by a manager of the assessment system (for example system 1000) or by a manger of an industrial system (for example system 10, 20, 30 or 40).

The orchestrator application may choose an execution queue for an execution task in a plurality of execution queues based on information in configuration files associated to the computational analysis computer programs.

Advantageously, the orchestrator application stores information regarding computational analyses already performed, in particular results of computational analyses already performed, in an orchestrator database (see for example database 220 in FIG. 1); such information may be useful for future “computational analyses”.

As explained, according to this “innovative assessment method”, the data input application (100 in FIG. 1) needs to query and insert data in the data database (110 in FIG. 1)

As explained, according to this “innovative assessment method”, the orchestrator application (200 in FIG. 1) needs to query and extract data from the data database (110 in FIG. 1) and the systems database (210 in FIG. 1).

Such communication with these two databases, preferably both these databases, may be carried out respectively through an Application Programming Interface associated to the data database and through an Application Programming Interface associated to the systems database.

It may also be provided that each or both of these two databases may be managed by a dedicated management application. So there may be a data database management application (190 in FIG. 1) and/or a systems database management application (290 in FIG. 1). The data input application, the orchestrator application and these management applications may be configured to communicate with each other for carrying out the operations provided by this “innovative assessment method”.

As will be better explained later, also the computational analysis computer programs and/or their configuration files may be accessed through a Application Programming Interface and/or may be managed through a programs management application (319 in FIG. 1). It is to be noted that according to some embodiments, the orchestrator application needs to access at least the programs configuration files.

The preparation of analysis tasks has just been described.

Each of the prepared analysis task has to be executed, unless there is a reason that does not allow or recommend execution. As a first example, if communication errors occur with a industrial system, a computational analysis relating to this industrial system may be not executed (even if prepared) or stopped during execution. As a second example, a computational analysis under test or debug may be not executed or stopped during execution if an error is identified before execution or during execution.

Execution is in principle independent from preparation.

According to the innovative subject matter disclosed herein, processing of an analysis task regarding a computational analysis on data received from an industrial system and stored in a data database for making an assessment on the industrial system is performed by an execution engine.

FIG. 1 shows a plurality of execution engines. In particular, the figure shows three execution engines 301, 302 and 303; however, any number of engines may be considered from a minimum of one. It is to be noted that execution engines may correspond for example to distinct physical machines but also to distinct virtual machines realized through the same piece of hardware. Furthermore, as it will be better described later, one or more or all of the execution engine may be local (i.e. in the same piece of hardware where the orchestrator application runs) or remote (i.e. in a piece of hardware distinct from the piece of hardware where the orchestrator application runs and close thereto of distant therefrom); any combination of these two possibilities may be considered. Typically, the creation of one or more virtual machines for the execution engine or engines is realized at the beginning; however, it is not to be excluded that it is realized during operation of an “innovative assessment system”.

In order to process an analysis task, an execution engine (e.g. engine 301):
a) collects execution parameters from a computational analysis computer program (see programs 311, 312 and 313 in FIG. 1) corresponding to the desired analysis task, the execution parameters comprising at least information on industrial system data to be processed by the computational analysis computer program,
b) extracts from the data database (database 110 in FIG. 1) data coming from the industrial system to be processed by the computational analysis computer program based on the collected execution parameters,
c) creates an execution environment containing at least the extracted data, and
d) executes the computational analysis computer program using the created execution environment.

The execution environment (that typically includes also the so-called “contest”) allows execution in an effective and efficient way: everything that is necessary for execution is within the environment so that after creation of the environment the engine does not need to access any data or information in particular to any database. Furthermore, execution may be carried out “wherever”, i.e. also remotely; for example, if execution of an analysis task is particularly computation intensive, it may be carried out for a remote “powerful engine” and the environment (including the “contest”) may be transmitted to the “powerful engine”.

Thanks to the creation of execution environments, execution of several analysis tasks may be carried out independently from each other.

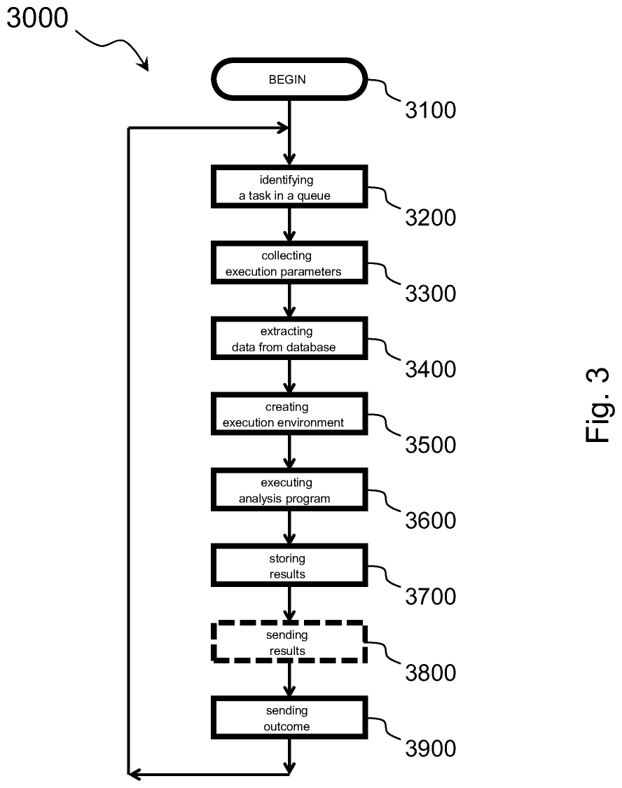

An “innovative assessment method” taking care of the execution of analysis tasks will now be described with the aid of the flow chart 3000 in FIG. 3.

In FIG. 3, there is an initial block 3100 corresponding to the ideal start of this method.

As explained above, it is assumed that an (real or virtual) execution engine is part of an “innovative assessment system”.

What described in the following applies to any execution engine, for example any of the engines 301, 302 and 303 in FIG. 1, and is continuously repeated.

Preliminarily, the execution engine identifies an analysis task to be executed in an execution queue (see for example queues 321, 322 and 323 in FIG. 1)—first actual step 3200 in the method of FIG. 3; typically, the identified task being at the top of the execution queue if a FIFO (First-In-First-Out) approach for managing the analysis tasks is followed; however, other approaches are possible. An execution engine may consider one (i.e. predetermined) or more execution queues; if more than one queue is considered, the execution engine may pick an analysis task in turn from the queues or may use some choice criterion.

Then, as already described, the execution engine:
a) (block 3300 in FIG. 3) collects execution parameters,
b) (block 3400 in FIG. 3) extracts data from the data database,
c) (block 3500 in FIG. 3) creates an execution environment, and
d) (block 3600 in FIG. 3) executes the computational analysis computer program.

As already described, any item in an execution queue, i.e. any analysis task, may contain at least the following information:
name or identifier of the computational analysis computer programs to be executed
name or identifier of the industrial system (or systems) to be assessed, i.e. to be subjected to analysis by the program-more in general, identification of the industrial system or systems to be analyzed through the task, for example a set of systems belonging to a same category or categories
timeframe, i.e. time range of data of the industrial system to be analyzed
Therefore, when an engine identifies a task in a queue many data and information are also identified and may be used by the engine for executing the task.

Following execution, i.e. step d, the execution engine may:
e) (block 3700 in FIG. 3) store results of execution in a results database (see for example database 410 in FIG. 1).

The results of the computational analysis performed in database 410 may be read and considered afterwards for example by the persons and/or the entity in charge of assessing the plurality of industrial systems.

It may be possible to provide in the “innovative assessment system” 1000 a data output application 400 that:
f) (block 3800 in FIG. 3) sends results in the results database 410 to a user application.

In this case, typically, sending data to user application is repeated e.g. periodically and is directed, typically, to a remote application. For example, a user that manages one or more plants may request another entity to take care of assessment of his plant(s) and be interested to receive from this entity results of the assessment; this entity may be specialized in such assessment activity.

It is to be noted that step f may be carried out for example taking information in systems database 210 into account. In fact, in systems database 210, for each industrial system a “client” information may be stored so that results of each analysis task may be directed for example by data output application 400 to the corresponding entity that owns or manages the industrial system.

Alternatively, it may be provided that results database 410 may be configured accessed locally for example from other applications inside the “innovative assessment system” or remotely for example from applications outside the “innovative assessment system”.

Advantageously, after step d and in particular after step e, the execution engine may:
g) (block 3900 in FIG. 3) send to an orchestrator application (for example application 200 in FIG. 1) information regarding an execution outcome.

In this way, depending on the information received, the orchestrator application may be aware of the computational analysis performed and their execution timeframe and/or whether they completed successfully and/or even, in some form, of the results of computational analysis performed. This may be used to the orchestrator application to prepare at best the following analysis tasks. It is to be noted that some computational analyses may require or take advantage of previous results.

Orchestrator application 200 may store the execution outcome received in orchestrator database 220.

The execution environment may contain also a reference to a computational analysis computer program (for example its name or a link to its code) specified in the queue item or a portion of the program or the whole program; the computational analysis computer program may be downloaded from a computational analysis database based on analysis task information for example in the queue item.

The execution environment may contain parameter(s) and/or constant(s) in general—see e.g. parameter(s) and/or constant(s) in the systems database.

The execution environment may contain also execution parameter(s) and/or constant(s) extracted from analysis task information for example in the queue item.

An execution parameter extracted from analysis task information may include information regarding computational analyses already performed, in particular results of computational analyses already performed, that may be stored in an orchestrator database.

Preferably, the execution engine arranges data in the execution environment according to a predetermined structure adapted to execution.

As explained, according to this “innovative assessment method”, the engines (301, 302 and 303 in FIG. 1) may need to query, insert data in and extract data from several items and/or databases (310, 320 and 410 in FIG. 1).

Such communication of the engines may be carried out through Application Programming Interfaces associated to the items and/or database. There may be an API associated to the programs or to the programs database and/or an API associated to the queues or to the queues database and/or an API associated to the results database.

It may also be provided that these databases may be managed by a dedicated management application. So there may be a programs database management application (319 in FIG. 1) and/or a queues database management application (329 in FIG. 1) and/or a results database management application (490 in FIG. 1). The engines and these management applications may be configured to communicate with each other for carrying out the operations provided by this “innovative assessment method”.

The embodiment of system in FIG. 1 includes all the components used for implementing both an “innovative assessment method” taking care of the preparation of analysis tasks and an “innovative assessment method” taking care of the execution of analysis tasks. According to alternative embodiments, an “innovative system” may include all the components used for implementing only an “innovative assessment method” taking care of the preparation of analysis tasks or only an “innovative assessment method” taking care of the execution of analysis tasks.

FIG. 1 shows a system 1000 comprising:
an orchestrator server 200
a data database 110
a systems database 210
an orchestrator database 220
a plurality of execution engines 301, 302 and 303
a plurality of computational analysis computer programs 311, 312 and 313 (in the figure there is a distinction between the computer programs as such, i.e. the executable code, that are shown as bigger boxes and the corresponding configuration files that are shown as a smaller boxes behind the bigger boxes)
a plurality of execution queues 321, 322 and 323, and
a results database 410.

Furthermore, FIG. 1 shows also a plurality of industrial systems 10, 20, 30 and 40 (to be accessed) that are not components of system and are typically remote and far away from the system.

Finally, FIG. 1 shows also some applications, in particular a first plurality of applications corresponding to basic applications and a second plurality of applications corresponding to database management applications.

The first plurality of applications comprises: a data input application 100 and a data output application 400. One or more or all of these applications may run on a dedicated “real machine”, i.e. a piece of hardware (that may be called “server”), or “virtual machine”.

The second plurality of applications comprises: a data database management application 190, a systems database management application 290, a programs management application 319, a queues database management application 329, a results database management application 490. All these applications are software applications; therefore, for each of them there is at least one corresponding computer program—as known, a software application may correspond to a set of computer programs to be run in order to perform the function or functions of the application. One or more or all of these applications may run on a dedicated “real machine”, i.e. a piece of hardware (that may be called “server”), or “virtual machine”.

Therefore, depending on how system 1000 is implemented elements 100, 190, 290, 319, 329, 490 and 400 may be hardware components of system 1000 or software components of system 1000.

Alternative system embodiments may include more components or less components than system 1000.

System 1000 may be split into a first subsystem and a second subsystem. The first subsystem includes elements 100, 110, 190, 200, 210, 220 and 290. The second subsystem includes elements 301, 302, 303, 311, 312, 313, 319, 321, 322, 323, 329, 400, 410 and 490. The split between these two subsystems may include cases wherein one or more hardware and/or software components are shared by the subsystems. For example, according to some embodiments, a server 200 may run in addition to an orchestrator application one or more of applications 100, 190 and 290. For example, according to some embodiments an execution engine and an orchestrator application may run on the same piece of hardware. For example, according to some embodiments, a first storage device may store programs 311, 312 and 313; the first storage device may be accessed by both the orchestrator application and the one or more execution engines; in this case, the first storage device (possibly including application or server 319) is shared by both subsystems. For example, according to some embodiments, a second storage device may store queues 321, 322 and 323; the second storage device may be accessed by both the orchestrator application and the one or more execution engines; in this case, the second storage device (possibly including application or server 329) is shared by both subsystems. For example, according to some embodiments, the first storage device and the second storage device may be part of a single storage system that is shared by both subsystems.

The first subsystem for making assessments industrial systems comprises at least:
access to systems database 210, i.e. not necessarily the whole database, but at least means for accessing the database,
access to data database 110, i.e. not necessarily the whole database, but at least means for accessing the database, and
orchestrator server 200 adequately configured as described above and that may incorporate or may have access to orchestrator database 220 through appropriate means.

The second subsystem for processing an analysis task comprises at least:
access to data database 110, i.e. not necessarily the whole database, but at least means for accessing the database,
access one or (more typically) several computational analysis computer programs 311, 312 and 313, i.e. not necessarily the program(s), but at least means for accessing the program(s),
at least one execution engine 301, 302 and 303 adequately configured as described above,
   and typically also
access one or (more typically) execution queues 321, 322 and 323, i.e. not necessarily the queue(s), but at least means for accessing the queue(s).

It is to be noted that the “execution environment” (typically including the “contest”) is created during execution of an analysis task by an execution engine. Therefore, it is not a true component of the system or subsystem. However, some computer memory is necessary for storing the “execution environment” when is created and/or when is used during execution of a computational analysis computer program. It is to be noted that, according to some embodiments, an “execution environment” may be transmitted remotely after being created and before being used during execution of a computational analysis computer program—this applies typically to remote execution of an analysis task.

As described above, an “innovative system” may include several components. Depending on how the system is implemented, components may be local to each other or remote from each other. In this context, the word “local” may mean inside the same “virtual machine” or inside the same “real machine” or inside the same computer or server, and the word “remote” may mean inside distinct “virtual machines” or inside distinct “real machines” or inside distinct computers or servers. Therefore, in this context, the meaning of these words does not necessarily relate to physical distance; for example, two components may be remote even if inside the same board or the same cabinet, i.e. at a distance of 1-100 cm. Of course, when the physical distance is long, the word “remote” generally applies.

In the previous paragraphs, reference has often been made to “access means” when describing databases, computer programs and execution queues, i.e. “entities” to be accessed. Such “access means” may be implemented in different ways. Advantageously, their implementation implies an Application Programming Interface (including one or more access primitives); in this way, “access” does not require to have detailed information on the entity to be accessed, in particular how the entity is internally implemented and/or where is the entity (e.g. remote or local, in case of a remote entity, access thereto may require for example communication through the Internet and/or through one or more hardware systems). An entity to be accesses, for example a database, may be managed by a management device associated to the entity; in this case, access to the entity implies communication with its management device; an Application Programming Interface may implement communication with the management device if and when necessary.

Considering the computer programs 311, 312 and 313, they may be stored somewhere, they may be managed by a management application 319 associated to a programs database; their configuration files may be included in the database. Application 200 has typically the need to access information in the configuration files. Execution engines 301, 302 and 303 have typically the need to access information in the configuration files and the need to download them.

As already said, FIG. 1 shows, by way of example, three execution engines 301, 302 and 303, all of them being fully internal to system 1000; as explained the minimum number of execution engine is one.

According to the simplest implementation of system 1000, each of the execution engines performs calculations locally, i.e. inside system 1000.

However, according to alternative embodiments, one or more of the execution engines may performs calculations remotely, in this case, for example, an execution engine prepares everything that is necessary for a calculation (including e.g. creating the execution environment and downloading the computational analysis computer programs) based on data and information in an execution queue, and then requests a remote “calculator system” or “calculator application” to perform calculation (typically sends both the created execution environment and the execution program) and waits for results to be subsequently stored in the results database 410. In this case, the execution engine may “branch out” of the system. It is to be noted that, according to some embodiments, part of the calculation may be performed locally and part of the calculation may be performed remotely.

It is apparent from the above description that systems as described herein, for example system 1000 of FIG. 1000, allow to implement the “As A Service” model in the field of industrial systems at different levels: IAAS (=Infrastructure As A Service) of special interest for the network architects and IT administrators, PAAS (=Platform As A Service) of special interest for software developers, and SAAS (=Software As A Service) of special interest for end users.

1. A method for processing an analysis task regarding a computational analysis on data received from an industrial system and stored in a data database for making an assessment on the industrial system, wherein an execution engine:
collects execution parameters from a computational analysis computer program corresponding to the analysis task, the execution parameters comprising information on industrial system data to be processed by the computational analysis computer program,
b) extracts from the data database-data coming from the industrial system to be processed by the computational analysis computer program based on the collected execution parameters,
c) creates an execution environment containing the extracted data, and
d) executes the computational analysis computer program using the created execution environment.

2. The method of claim 1, wherein the execution engine identifies the analysis task in an execution queue, in particular a predetermined execution queue, the identified task being at the top of the execution queue.

3. The method of claim 1, wherein the execution engine identifies the analysis task in a plurality of execution queues, the identified task being at the top of any execution queues.

4. The method of claim 2, wherein the execution engine identifies the analysis task database through an Application Programming Interface associated to the queue or queues.

5. The method of claim 1, wherein at step a) the execution engine collects execution parameters from a computational analysis computer program through an Application Programming Interface associated to computational analysis computer programs.

6. The method of claim 1, wherein at step b) the execution engine extracts data from the data database through an Application Programming Interface associated to the data database.

7. The method of claim 1, wherein at step c) the execution environment contains also a reference to a computational analysis computer program or a portion of a computational analysis computer program or the whole computational analysis computer program, wherein the computational analysis computer program may be downloaded from a computational analysis database based on analysis task information.

8. The method of claim 1, wherein at step c) the execution environment contains also execution parameters extracted from analysis task information.

9. The method of claim 8, wherein an execution parameter extracted from analysis task information includes information regarding computational analyses already performed, in particular results of computational analyses already performed, that may be stored in an orchestrator database.

10. The method of claim 1, wherein at step c) the execution engine arrange data in the execution environment according to a predetermined structure adapted to execution.

11. The method of claim 1, wherein after step d) the execution engine:
e) stores results of execution in a results database.

12. The method of claim 11, wherein at step e) the execution engine stores results of execution in a results database through an Application Programming Interface associated to the results database.

13. The method of claim 11, wherein the results database is configured to be accessed locally or remotely.

14. The method of claim 11, wherein a data output application:
f) sends results in the results database to a user application.

15. The method of claim 1, wherein after step d), in particular after step e), the execution engine:
g) sends to an orchestrator application information regarding an execution outcome.

16. A system for processing an analysis task regarding a computational analysis on data received from an industrial system and stored in a data database for making an assessment on the industrial system wherein the system comprises:
access to a data database storing data collected from industrial systems,
access to at least one computational analysis computer program, and
at least one execution engine configured to:
a) collect execution parameters from the computational analysis computer program corresponding to the analysis task, the execution parameters comprising information on industrial system data to be processed by the computational analysis computer program,
b) extract from the data database data coming from the industrial system to be processed by the computational analysis computer program based on the collected execution parameters,
c) create an execution environment containing the extracted data, and
d) execute the computational analysis computer program using the created execution environment.

17. The system of claim 16, wherein the system comprises further the data database, wherein the data database is local or remote.

18. The system of claim 16, wherein the system comprises further one or more computational analysis computer programs and/or a computational analysis database, wherein the computational analysis database is local or remote.

19. The system of claim 16, wherein the system comprises further one or more queues configured to store analysis tasks and/or a queue database, wherein the queues database is local or remote.

20. The system of claim 16, wherein the system comprises further the results database, wherein the results database is local or remote.
